(19) United States
(12) Patent Application Publication
(10) Pub. No.: US 2024/0213126 A1
(43) Pub. Date: Jun. 27, 2024

(54) SEMICONDUCTOR DEVICE

(71) Applicant: POWER MASTER SEMICONDUCTOR CO., LTD., Cheongju-si (KR)

(72) Inventors: Jooyaung EOM, Gimpo-si (KR); In-Suk KIM, Bucheon-si (KR); Ki-Myung YOON, Bucheon-si (KR); Taekkeun LEE, Seoul (KR); Soonho KWON, Bucheon-si (KR)

(21) Appl. No.: 18/544,774

(22) Filed: Dec. 19, 2023

(30) Foreign Application Priority Data
Dec. 27, 2022 (KR) 10-2022-0186101
Oct. 31, 2023 (KR) 10-2023-0148302

(51) Int. Cl. H01L 23/495; H01L 23/00; H01L 23/31; H01L 23/367

(52) U.S. Cl. CPC H01L 23/49568; H01L 23/3121; H01L 23/3675; H01L 23/49537; H01L 23/49562; H01L 24/40; H01L 24/48; H01L 24/73; H01L 2224/40175; H01L 2224/48175; H01L 2224/73221; H01L 2924/182

(57) ABSTRACT

A semiconductor device is provided. The semiconductor device may include a heat dissipation pad that is formed such that the upper surface is exposed to the outside of a molding portion, a first lead frame that is formed on the left side of the heat dissipation pad so as to be spaced apart from the heat dissipation pad and includes a first portion extending in an upward and downward direction and a second portion protruding in a right direction, second lead frames that are formed on the right side of the heat dissipation pad, a first connection part that is formed so as to be connected to both of the lower surface of the heat dissipation pad and the lower surface of the second portion of the first lead frame, a semiconductor chip that is formed on the lower surface of the heat dissipation pad, and a second connection part that connects the semiconductor chip and the second lead frames.

### CROSS-REFERENCE TO RELATED APPLICATION

This application claims priority to and the benefit of Korean Patent Application No. 10-2022-0186101 filed in the Korean Intellectual Property Office on Dec. 27, 2022, and Korean Patent Application No. 10-2023-0148302 filed in the Korean Intellectual Property Office on Oct. 31, 2023, the entire contents of which are incorporated herein by reference.

### BACKGROUND OF THE INVENTION

### (a) Field of the Invention

The present disclosure relates to a semiconductor device.

### (b) Description of the Related Art

Power semiconductor devices are semiconductor devices for transferring, controlling, and converting power, and are becoming increasingly important especially in high-power applications, like those for eco-friendly vehicles such as hybrid electric vehicles (HEVs), electric vehicles (EVs), plug-in hybrid electric vehicles (PHEVs), and fuel cell electric vehicles (FCEVs). Power semiconductor devices are required to be capable of handling high current and voltage and thus are required to have high efficiency and stability. For example, insulated gate bipolar transistors (IGBTs) are power electronics devices which have high-input impedance characteristics like metal oxide semiconductor field effect transistors (MOSFETs) and also have low conduction loss characteristics like bipolar junction transistors (BJTs), and are suitable for applications that require high switching speed while maintaining high voltage. As another example, silicon carbide (SiC) is a high-performance semiconductor material having higher electrical conductivity, higher thermal conductivity, the ability to operate devices at higher temperatures, higher voltage and current densities, higher switching speeds, as compared to silicon, and SiC semiconductors may be suitable for high-power, high-temperature, or high-frequency applications. Power semiconductor devices generate significant amounts of heat during operation, and if this heat is accumulated in the devices, it may cause serious damage. Therefore, thermal management is a critical consideration in designing power semiconductor packages, and measures for quickly and effectively dispersing heat are required.

### SUMMARY OF THE INVENTION

The present disclosure attempts to provide a semiconductor device capable of increasing the heat dissipation effect without increasing the package size of a power semiconductor device.

The present disclosure also attempts to provide a semiconductor device capable of rigidly forming the package of a power semiconductor device such that occurrence of warpage is reduced, and increasing the bonding area between the semiconductor device and a printed circuit board (PCB) that is connected to the power semiconductor device such that solder cracking due to vibration and thermal shock is improved.

A semiconductor device according to an embodiment may include a heat dissipation pad that is formed such that the upper surface is exposed to the outside of a molding portion, a first lead frame that is formed on the left side of the heat dissipation pad so as to be spaced apart from the heat dissipation pad and includes a first portion extending in an upward and downward direction and a second portion protruding in a right direction, second lead frames that are formed on the right side of the heat dissipation pad, a first connection part that is formed so as to be connected to both of the lower surface of the heat dissipation pad and the lower surface of the second portion of the first lead frame, a semiconductor chip that is formed on the lower surface of the heat dissipation pad, and a second connection part that connects the semiconductor chip and the second lead frames.

In some embodiments, a portion of the molding portion may be filled between the left side surface of the heat dissipation pad and the right side surface of the second portion of the first lead frame.

In some embodiments, the lower surface of the first lead frame may be formed together with the lower surface of the heat dissipation pad on the same plane.

In some embodiments, some portions of the upper surface of the second portion of the first lead frame may be exposed to the outside of the molding portion, and the other portions may not be exposed to the outside of the molding portion.

In some embodiments, the upper surface of the first lead frame may be formed together with the upper surface of the heat dissipation pad on the same plane.

In some embodiments, the entire upper surface of the second portion of the first lead frame may be exposed to the outside of the molding portion.

In some embodiments, on the left side surface of the heat dissipation pad, a pair of protrusions may be formed so as to protrude toward the first portion of the first lead frame.

In some embodiments, the upper surfaces of the pair of protrusions may form a step with the upper surface of the heat dissipation pad, and the lower surfaces of the pair of protrusions may be formed together with the lower surface of the heat dissipation pad on the same plane.

In some embodiments, the upper surfaces of the pair of protrusions may be formed together with the upper surface of the heat dissipation pad on the same plane, and the lower surfaces of the pair of protrusions may form a step with the lower surface of the heat dissipation pad.

In some embodiments, the pair of protrusions may be formed so as to be spaced apart from each other in the upward and downward direction, and the second portion of the first lead frame may be formed between the pair of protrusions.

In some embodiments, some portions of the molding portion may be filled between the pair of protrusions and the second portion of the first lead frame.

In some embodiments, the first portion of the first lead frame may include a pair of cut surfaces which are formed by cutting portions in which the first portion is connected to the pair of protrusions.

In some embodiments, the first connection part may include a clip, and the second connection part may include wiring lines.

According to the embodiments, it is possible to increase the heat dissipation effect without increasing the package size of a power semiconductor device. Also, it is possible to rigidly form the package of a power semiconductor device such that occurrence of warpage is reduced, and increase the bonding area between the semiconductor device and a printed circuit board (PCB) that is connected to the power semiconductor device such that solder cracking due to vibration and thermal shock is improved.

### BRIEF DESCRIPTION OF THE DRAWINGS

FIG. 1 to FIG. 4 are drawings for explaining a semiconductor device according to an embodiment.

FIG. 5 to FIG. 8 are drawings for explaining a semiconductor device according to an embodiment.

### DETAILED DESCRIPTION OF THE EMBODIMENTS

Hereinafter, embodiments of the present invention will be described in detail with reference to the accompanying drawings such that those skilled in the art can easily implement them. However, the present invention can be implemented in various different forms and is not limited to the following embodiments. The drawings are to be regarded as illustrative in nature and not restrictive. Like reference numerals designate like elements throughout the specification.

Throughout the specification and the claims, unless explicitly described to the contrary, the word “comprise”, and variations such as “comprises” or “comprising”, will be understood to imply the inclusion of stated elements but not the exclusion of any other elements. Meanwhile, throughout the specification and the claims, the terms “up”, “down”, “left” and “right” are relatively defined based on the accompanying drawings only for clearly and easily explaining embodiments, and it is clear that they are not intended to limit any component to an absolute specific direction in the present invention.

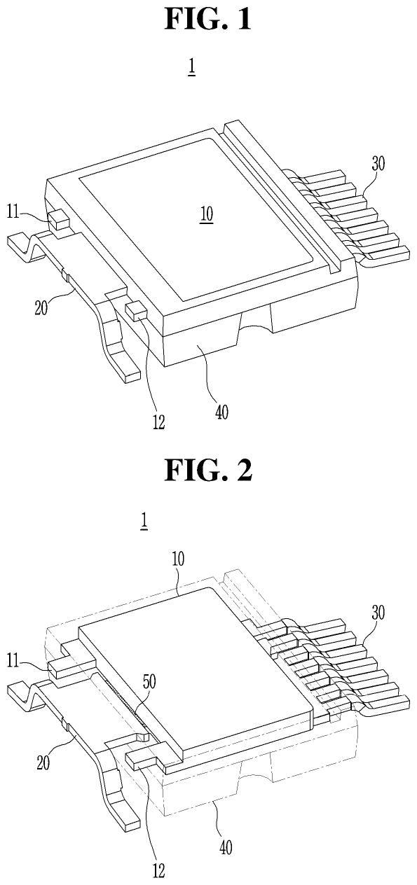

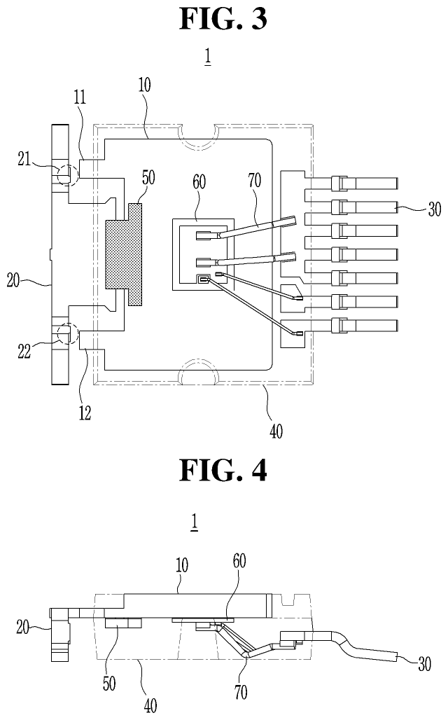

FIG. 1 to FIG. 4 are drawings for explaining a semiconductor device according to an embodiment.

Referring to FIG. 1 to FIG. 4, a semiconductor device 1 according to an embodiment may include a heat dissipation pad 10, a first lead frame 20, second lead frames 30, a molding portion 40, a first connection part 50, a semiconductor chip 60, and second connection parts 70.

The semiconductor chip 60 may be a power semiconductor device. For example, the semiconductor chip 60 may include various types of power devices such as insulated gate bipolar transistors (IGBTs) and silicon carbide (SiC) devices. Therefore, the semiconductor device 1 may be a power semiconductor device package. The semiconductor chip 60 operates under a high-power and high-voltage condition due to the nature of power semiconductor devices, and thus may generate a significant amount of heat. For clarity and convenience of description, in the drawings, one semiconductor chip 60 is shown; however, the scope of the present invention is not limited thereto. In other words, the semiconductor chip 60 may be formed of a plurality of chips depending on the specific implementation purpose, the implementation environments, and operation requirements, unlike in the drawings.

The heat dissipation pad 10 may absorb heat that is generated by the semiconductor chip 60, and transfer the heat to the surrounding environment of the semiconductor device 1, thereby quickly dispersing the heat. To this end, the heat dissipation pad 10 may be made of a metal with high thermal conductivity, such as copper, aluminum, etc. The heat dissipation pad 10 may be formed to be in direct physical contact with one surface of the semiconductor chip 60, such that it effectively absorbs heat that is generated by the semiconductor chip 60. Specifically, the semiconductor chip 60 may be formed on the lower surface of the heat dissipation pad 10.

The molding portion 40 may fix and protect the semiconductor chip 60 and other components mounted in the semiconductor device 1. For example, the molding portion 40 may protect the semiconductor chip 60 and other components from dust, moisture, oxidation, and other chemicals in the external environment, and fix the connection between these elements and the package. The molding portion 40 may be formed of a sealing material such as an epoxy molding compound (EMC), and the EMC may be made of a composite material comprising several raw materials such as silica, epoxy resins, phenolic resins, carbon black, frame retardant materials, etc. Of course, the material of the molding portion 40 is not limited to the EMC, and various arbitrary materials may be used.

The heat dissipation pad 10 may be formed such that its upper surface is exposed to the outside of the molding portion 40. Since the lower surface of the heat dissipation pad 10 is in direct physical contact with the semiconductor chip 60, the heat dissipation pad can absorb heat and quickly disperse the heat through the upper surface. Meanwhile, the heat dissipation pad 10 may be formed so as to be covered by the molding portion 40, except for the upper surface exposed to the outside. As described above, four side surfaces of the heat dissipation pad 10 may be covered by the molding portion 40 and only the upper surface is exposed to the outside, whereby it is possible to reduce warpage of the package while maximizing the bonding area when a heat sink is formed on the heat dissipation pad 10. Therefore, it is possible to increase the heat dissipation effect while securing the rigidity of the package.

The first lead frame 20 may provide an electrical connection between the semiconductor chip 60 and another PCB. To this end, the first lead frame 20 may contain a variety of electrically conductive materials such as copper, aluminum, an alloy thereof, etc.

In the present embodiment, the first lead frame 20 may not be formed integrally with the heat dissipation pad 10, and may be formed as a separate component that is physically spaced apart. In the drawings, the first lead frame 20 may be formed on the left side of the heat dissipation pad 10 so as to be spaced apart from the heat dissipation pad 10. The first lead frame 20 may include a first portion and a second portion. As shown in the drawings, the first portion may represent a portion of the first lead frame 20 extending in the upward and downward direction as seen in the drawings, and the second portion may represent a portion protruding in the right direction as seen in the drawings. Since the first lead frame 20 is formed so as to be spaced apart from the heat dissipation pad 10, a portion of the molding portion 40 may be filled between the left side surface of the heat dissipation pad 10 and the right side surface of the second portion of the first lead frame 20 as seen in the drawings.

The first connection part 50 may be formed to be connected to both of the lower surface of the heat dissipation pad 10 and the lower surface of the second portion of the first lead frame 20. In other words, the heat dissipation pad 10 and the first lead frame 20 made as separate components may be electrically connected through the first connection part 50 made as a separate component. In some embodiments, the first connection part 50 may include a clip. In other words, the first connection part 50 may realize clip bonding to the heat dissipation pad 10 and the first lead frame 20. Since clip bonding is adopted between the heat dissipation pad 10 and the first lead frame 20, it is possible to secure shorter power and signal paths as compared to wire bonding. Therefore, it is possible to improve the electrical performance of the semiconductor device 1, and it is possible to withstand higher current and provide higher thermal conductivity and better durability. However, in some other embodiments, the first connection part 50 may be formed of wire. In other words, the first connection part 50 may realize wire bonding to the heat dissipation pad 10 and the first lead frame 20, and in the case of wire bonding, the advantageous effects due to the package structure of the semiconductor device 1 which is described in the present embodiment may still be expected.

When the first connection part 50 includes a clip, since the first lead frame 20 is formed so as to be spaced apart from the heat dissipation pad 10, of the upper surface of the first connection part 50, the whole of the portion which is exposed between the left side surface of the heat dissipation pad 10 and the right side surface of the second portion of the first lead frame 20 as seen in the drawings may be in direct contact with the molding portion 40.

Similar to the first lead frame 20, the second lead frames 30 may also provide electrical connections between the semiconductor chip 60 and other PCBs, and to this end, the second lead frames 30 may also contain a variety of electrically conductive materials such as copper, aluminum, an alloy thereof, etc. At least some of the second lead frames 30 may serve as source terminals, or serve as drain terminals, or serve as gate terminals. In the present embodiment, as seen in the drawings, the second lead frames 30 may be formed on the right side of the heat dissipation pad 10, and the second connection part 70 may connect the semiconductor chip 60 and the second lead frames 30. In some embodiments, the second connection part 70 may include wiring lines. In other words, the second connection part 70 may realize wire bonding to the semiconductor chip 60 and the second lead frames 30.

In the present embodiment, on the left side surface of the heat dissipation pad 10 as seen in the drawings, a pair of protrusions 11 and 12 may be formed so as to protrude toward the first portion of the first lead frame 20. Further, the first portion of the first lead frame 20 may include a pair of cut surfaces 21 and 22 which are formed by cutting portions in which the first portion is connected to the pair of protrusions 11 and 12. The pair of protrusions 11 and 12 and the pair of cut surfaces 21 and 22 may be physically connected before a process of forming the molding portion 40 is performed during the process of manufacturing the semiconductor device 1. Accordingly, before fixing and protection by the molding portion 40 is secured, it is possible to prevent deformation of components such as the heat dissipation pad 10 that may occur during the manufacturing process and occurrence of warpage due to vibration that may occur during the manufacturing process. If the process of forming the molding portion 40 is completed, the physically connected portions may be cut and the first portion of the first lead frame 20 may be bent to meet product requirements. Thereafter, the pair of protrusions 11 and 12 may be left on the heat dissipation pad 10, and the pair of cut surfaces 21 and 22 may be left on the first portion of the first lead frame 20.

Here, as seen in the drawings, the pair of protrusions 11 and 12 may be formed so as to be spaced apart from each other in the upward and downward direction and the second portion of the first lead frame 20 may be formed between the pair of protrusions 11 and 12. Further, some portions of the molding portion 40 may be filled between the pair of protrusions 11 and 12 and the second portion of the first lead frame 20.

Meanwhile, in the present embodiment, the lower surface of the first lead frame 20 may be formed together with the lower surface of the heat dissipation pad 10 on the same plane. Accordingly, in the first lead frame 20, some portions of the upper surface of the second portion may be exposed to the outside of the molding portion 40, and the other portions of the upper surface of the second portion may not be exposed to the outside of the molding portion 40. Meanwhile, the upper surfaces of the pair of protrusions 11 and 12 may form a step with the upper surface of the heat dissipation pad 10, and the lower surfaces of the pair of protrusions 11 and 12 may be formed together with the lower surface of the heat dissipation pad 10 on the same plane. Since the lower surface of the first lead frame 20 is formed on a level with the lower surface of the heat dissipation pad 10, the first lead frame 20 connectable to a PCB may be formed longer. Accordingly, the effect of increasing the soldering area between the first lead frame 20 and a PCB may be achieved.

According to the present embodiment, from the structure and the configuration described above, including the heat dissipation pad 10, the first lead frame 20, and the first connection part 50, it is possible to minimize the volume which is occupied by the package while increasing the heat dissipation efficiency, and it is possible to reduce occurrence of warpage and increase the bonding area between the semiconductor device and a PCB such that solder cracking due to vibration and thermal shock is improved. Therefore, it is possible to secure the stability and reliability of the package.

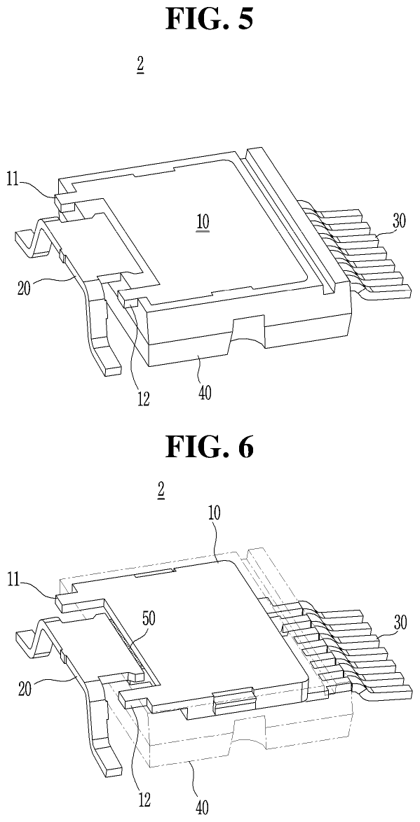

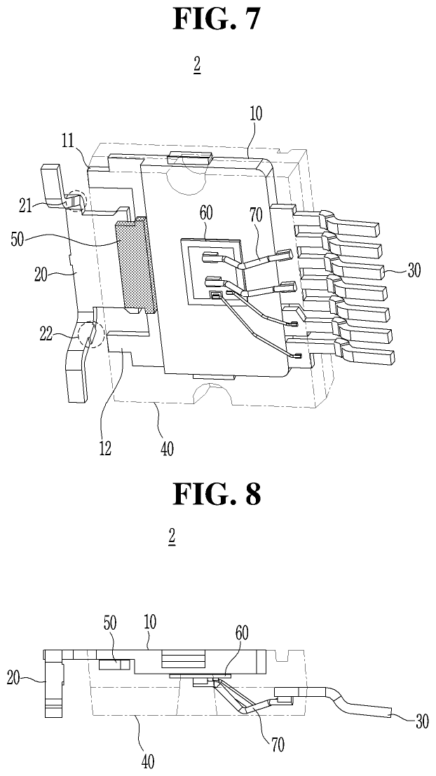

FIG. 5 to FIG. 8 are drawings for explaining a semiconductor device according to an embodiment.

Referring to FIG. 5 to FIG. 8, a semiconductor device 2 according to an embodiment may include a heat dissipation pad 10, a first lead frame 20, second lead frames 30, a molding portion 40, a first connection part 50, a semiconductor chip 60, and second connection parts 70. Here, as for the second lead frames 30, the molding portion 40, the semiconductor chip 60, and the second connection part 70, the contents described above with reference to FIG. 1 to FIG. 4 may be referred to and applied. Therefore, a redundant description thereof will not be made here.

The heat dissipation pad 10 may absorb heat that is generated by the semiconductor chip 60, and transfer the heat to the surrounding environment of the semiconductor device 2, thereby quickly dispersing the heat. To this end, the heat dissipation pad 10 may be made of a metal with high thermal conductivity, such as copper, aluminum, etc. The heat dissipation pad 10 may be formed to be in direct physical contact with one surface of the semiconductor chip 60, such that it effectively absorbs heat that is generated by the semiconductor chip 60. Specifically, the semiconductor chip 60 may be formed on the lower surface of the heat dissipation pad 10.

The heat dissipation pad 10 may be formed such that its upper surface is exposed to the outside of the molding portion 40. Since the lower surface of the heat dissipation pad 10 is in direct physical contact with the semiconductor chip 60, the heat dissipation pad can absorb heat and quickly disperse the heat through the upper surface. Meanwhile, the heat dissipation pad 10 may be formed so as to be covered by the molding portion 40, except for the upper surface exposed to the outside. As described above, four side surfaces of the heat dissipation pad 10 may be covered by the molding portion 40 and only the upper surface is exposed to the outside, whereby it is possible to reduce warpage of the package while maximizing the bonding area when a heat sink is formed on the heat dissipation pad 10. Therefore, it is possible to increase the heat dissipation effect while securing the rigidity of the package.

The first lead frame 20 may provide an electrical connection between the semiconductor chip 60 and another PCB. To this end, the first lead frame 20 may contain a variety of electrically conductive materials such as copper, aluminum, an alloy thereof, etc.

In the present embodiment, the first lead frame 20 may not be formed integrally with the heat dissipation pad 10, and may be formed as a separate component that is physically spaced apart. In the drawings, the first lead frame 20 may be formed on the left side of the heat dissipation pad 10 so as to be spaced apart from the heat dissipation pad 10. The first lead frame 20 may include a first portion and a second portion. As shown in the drawings, the first portion may represent a portion of the first lead frame 20 extending in the upward and downward direction as seen in the drawings, and the second portion may represent a portion protruding in the right direction as seen in the drawings. Since the first lead frame 20 is formed so as to be spaced apart from the heat dissipation pad 10, a portion of the molding portion 40 may be filled between the left side surface of the heat dissipation pad 10 and the right side surface of the second portion of the first lead frame 20 as seen in the drawings.

The first connection part 50 may be formed to be connected to both of the lower surface of the heat dissipation pad 10 and the lower surface of the second portion of the first lead frame 20. In other words, the heat dissipation pad 10 and the first lead frame 20 made as separate components may be electrically connected through the first connection part 50 made as a separate component. In some embodiments, the first connection part 50 may include a clip. In other words, the first connection part 50 may realize clip bonding to the heat dissipation pad 10 and the first lead frame 20. Since clip bonding is adopted between the heat dissipation pad 10 and the first lead frame 20, it is possible to secure shorter power and signal paths as compared to wire bonding. Therefore, it is possible to improve the electrical performance of the semiconductor device 2, and it is possible to withstand higher current and provide higher thermal conductivity and better durability. However, in some other embodiments, the first connection part 50 may be formed of wire. In other words, the first connection part 50 may realize wire bonding to the heat dissipation pad 10 and the first lead frame 20, and in the case of wire bonding, the advantageous effects due to the package structure of the semiconductor device 2 which is described in the present embodiment may still be expected. Alternatively, in some other embodiments, the first connection part 50 may be formed of an arbitrary conductive material.

When the first connection part 50 includes a clip, since the first lead frame 20 is formed so as to be spaced apart from the heat dissipation pad 10, of the upper surface of the first connection part 50, the whole of the portion which is exposed between the left side surface of the heat dissipation pad 10 and the right side surface of the second portion of the first lead frame 20 as seen in the drawings may be in direct contact with the molding portion 40.

In the present embodiment, on the left side surface of the heat dissipation pad 10 as seen in the drawings, a pair of protrusions 11 and 12 may be formed so as to protrude toward the first portion of the first lead frame 20. Further, the first portion of the first lead frame 20 may include a pair of cut surfaces 21 and 22 which are formed by cutting portions in which the first portion is connected to the pair of protrusions 11 and 12. The pair of protrusions 11 and 12 and the pair of cut surfaces 21 and 22 may be physically connected before a process of forming the molding portion 40 is performed during the process of manufacturing the semiconductor device 2. Accordingly, before fixing and protection by the molding portion 40 is secured, it is possible to prevent deformation of components such as the heat dissipation pad 10 that may occur during the manufacturing process and occurrence of warpage due to vibration that may occur during the manufacturing process. If the process of forming the molding portion 40 is completed, the physically connected portions may be cut and the first portion of the first lead frame 20 may be bent to meet product requirements. Thereafter, the pair of protrusions 11 and 12 may be left on the heat dissipation pad 10, and the pair of cut surfaces 21 and 22 may be left on the first portion of the first lead frame 20.

Here, as seen in the drawings, the pair of protrusions 11 and 12 may be formed so as to be spaced apart from each other in the upward and downward direction and the second portion of the first lead frame 20 may be formed between the pair of protrusions 11 and 12. Further, some portions of the molding portion 40 may be filled between the pair of protrusions 11 and 12 and the second portion of the first lead frame 20.

Meanwhile, in the present embodiment, the upper surface of the first lead frame 20 may be formed together with the upper surface of the heat dissipation pad 10 on the same plane. Accordingly, in the first lead frame 20, the entire upper surface of the second portion may be exposed to the outside of the molding portion 40. Meanwhile, the upper surfaces of the pair of protrusions 11 and 12 may be formed together with the upper surface of the heat dissipation pad 10 on the same plane, and the lower surfaces of the pair of protrusions 11 and 12 may form a step with the lower surfaces of the heat dissipation pad 10. Since the upper surface of the first lead frame 20 is formed on a level with the upper surface of the heat dissipation pad 10, the first lead frame 20 connectable to a PCB may be formed further longer. Accordingly, the effect of further increasing the soldering area between the first lead frame 20 and a PCB may be achieved.

According to the embodiments described herein, it is possible to increase the heat dissipation effect without increasing the package size of a power semiconductor device. Also, it is possible to rigidly form the package of a power semiconductor device such that occurrence of warpage is reduced, and increase the bonding area between the semiconductor device and a printed circuit board (PCB) that is connected to the power semiconductor device such that solder cracking due to vibration and thermal shock is improved.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor device comprising:
a heat dissipation pad that is formed such that the upper surface is exposed to the outside of a molding portion;
a first lead frame that is formed on the left side of the heat dissipation pad so as to be spaced apart from the heat dissipation pad and includes a first portion extending in an upward and downward direction and a second portion protruding in a right direction;
second lead frames that are formed on the right side of the heat dissipation pad;
a first connection part that is formed so as to be connected to both of the lower surface of the heat dissipation pad and the lower surface of the second portion of the first lead frame;
a semiconductor chip that is formed on the lower surface of the heat dissipation pad; and
a second connection part that connects the semiconductor chip and the second lead frames.

2. The semiconductor device of claim 1, wherein
a portion of the molding portion is filled between the left side surface of the heat dissipation pad and the right side surface of the second portion of the first lead frame.

3. The semiconductor device of claim 1, wherein
the lower surface of the first lead frame is formed together with the lower surface of the heat dissipation pad on the same plane.

4. The semiconductor device of claim 3, wherein
some portions of the upper surface of the second portion of the first lead frame are exposed to the outside of the molding portion, and the other portions are not exposed to the outside of the molding portion.

5. The semiconductor device of claim 1, wherein
the upper surface of the first lead frame is formed together with the upper surface of the heat dissipation pad on the same plane.

6. The semiconductor device of claim 5, wherein
the entire upper surface of the second portion of the first lead frame is exposed to the outside of the molding portion.

7. The semiconductor device of claim 1, wherein
on the left side surface of the heat dissipation pad, a pair of protrusions are formed so as to protrude toward the first portion of the first lead frame.

8. The semiconductor device of claim 7, wherein
the upper surfaces of the pair of protrusions form a step with the upper surface of the heat dissipation pad, and
the lower surfaces of the pair of protrusions are formed together with the lower surface of the heat dissipation pad on the same plane.

9. The semiconductor device of claim 7, wherein
the upper surfaces of the pair of protrusions are formed together with the upper surface of the heat dissipation pad on the same plane, and
the lower surfaces of the pair of protrusions form a step with the lower surface of the heat dissipation pad.

10. The semiconductor device of claim 7, wherein
the pair of protrusions are formed so as to be spaced apart from each other in the upward and downward direction, and
the second portion of the first lead frame is formed between the pair of protrusions.

11. The semiconductor device of claim 10, wherein
some portions of the molding portion are filled between the pair of protrusions and the second portion of the first lead frame.

12. The semiconductor device of claim 7, wherein
the first portion of the first lead frame includes a pair of cut surfaces which are formed by cutting portions in which the first portion is connected to the pair of protrusions.

13. The semiconductor device of claim 1, wherein
the first connection part includes a clip, and the second connection part includes wiring lines.
